(19) United States
(12) Patent Application Publication
(10) Pub. No.: US 2025/0073842 A1
(43) Pub. Date: Mar. 6, 2025

(54) MULTILAYER CMP PADS

(71) Applicants: Rajeev BAJAJ, SAN JOSE, CA (US); Ananth NAMAN, TAMPA, FL (US)

(72) Inventors: Rajeev BAJAJ, SAN JOSE, CA (US); Ananth NAMAN, TAMPA, FL (US)

(21) Appl. No.: 18/710,642

(22) PCT Filed: Sep. 3, 2023
(86) PCT No.: PCT/US23/31943

§ 371 Date: May 16, 2024

(51) Int. Cl. B24B 37/22; B24B 37/24

(52) U.S. Cl. CPC B24B 37/22; B24B 37/24

(57) ABSTRACT

A polishing pad comprising a textile layer, a compressible layer, and a water impermeable layer disposed between the textile layer and the compressible layer. The polishing pad reduces slurry use by improving slurry transport and requires no diamond conditioning to maintain slurry transport.

### FIELD OF THE INVENTION

The present invention relates generally to the field of chemical mechanical planarization (CMP), and more specifically to a CMP polishing pad utilized in CMP processing.

### BACKGROUND OF THE INVENTION

In modern integrated circuit (IC) fabrication, layers of material are applied to embedded structures previously formed on semiconductor wafers. Chemical mechanical planarization, also known as chemical mechanical polishing (hereinafter referred to also as CMP) is an abrasive process used to remove these layers and polish the surface of a wafer flat to achieve the desired structure.

### Multilayer CMP Pads

CMP may be performed on both oxide and metal films and generally involves the use of chemical slurries applied via a polishing pad that is moved relative to the wafer (e.g., the pad may rotate circularly relative to the wafer). The resulting smooth, flat surface is necessary to maintain the photolithographic depth of focus for subsequent steps and to ensure that the metal interconnects are not deformed over contour steps. Damascene processing requires CMP to remove metals, such as tungsten or copper, from the top surface of a dielectric to define interconnect structures.

The planarization/polishing performance of a pad/slurry combination is impacted by, among other things, the thermomechanical and chemical properties, as well as ability for uniform slurry distribution ability. Typically, hard (i.e., stiff) pads provide good planarization, but are associated with poor with-in wafer non-uniformity (WIWNU) film removal and higher propensity to cause micro-scratch defects. Soft (i.e., flexible) pads, on the other hand, provide polishing with good WIWNU, but poor planarization. In conventional CMP systems, therefore, harder pads are used for bulk film removal and planarization of features while soft pads are used for finer polish and removal of micro-scratch defects as well as substantial removal of slurry abrasive particles prior to cleaning in a post CMP cleaner.

FIG. 1 shows a typical polish system. A polishing pad 102 is affixed to a polishing table 100 with a pressure sensitive adhesive. A wafer 106 is held by a wafer holder 104 and pressed against the polishing pad 102 while both the polishing table 100 and the wafer holder 104 are rotated around their respective axes and slurry 110 is applied to the polishing pad.

Conventional polishing pads are typically made of urethanes, either in cast form and filled with micro-porous elements or from non-woven felt coated with polyurethanes. Soft pads are made from the two processes above as well as a solution precipitation method, wherein polymer is dissolved in a water miscible solvent and then precipitated out by adding water as non-solvent. This results in a highly porous pad surface with good polish properties.

FIG. 2 illustrates a side cutaway view of a hard polishing pad 200. Polishing pad 200 consists of a urethane matrix with micro-porous elements 202 and grooves 204, and base pad 206 much like those found in commercially available polishing pads such as the IC1000 commercially available by Dupont Electronic Materials.

FIG. 3 shows a soft polishing pad 300. Polishing pad 300 contains urethane matrix 302 and vertically oriented pores 304. Pad surface may be optionally embossed to provide channels for enhanced slurry distribution at the wafer-pad interface.

As polishing is accomplished by applying pressure and motion against the wafer, the pad material undergoes deformation. This deformation leads to smoothening of the pad surface, which must then be roughened to accomplish continued wafer polishing. The process of roughening of the pad surface, a process called pad conditioning, is accomplished by pressing a rotating disk covered with fine diamonds, against a rotating pad. This restores pad roughness enabling local slurry transport. Polishing pad therefore, requires grooving, pores, and micro roughness to affect uniform polish process. Stable polish performance requires optimization of grooving for macro transport, porosity, and diamond conditioning for local slurry transport. Excess slurry is supplied on the pad to enable sufficient slurry for uniform distribution across the wafer-pad interface. It will be advantageous to have a pad that can reduce slurry usage by improving slurry transport and requires no diamond conditioning to maintain slurry transport.

### SUMMARY OF THE INVENTION

According to an aspect of the present invention, a CMP polishing pad is provided which is utilized in CMP processing. The CMP polishing pad reduces slurry usage by improving slurry transport and requires no diamond conditioning for maintaining slurry transport.

In accordance with an embodiment of the present invention, a polishing pad may be configured to include a textile layer, a water impervious layer and a compressible layer. The first side of the textile layer may form the polish surface, while the second surface may be adhered to the first side of impervious layer. The second side of impervious layer may be adhered to the first side of the compressible layer. The second side of compressible layer may be affixed to the polish table by a pressure sensitive adhesive.

In an embodiment, the base fabric of the textile layer that forms the polish surface may be woven to provide a controlled, structured surface. However, in another embodiment, the base fabric of the textile layer may be knitted. Several technologies in weaving and knitting that enable creating precise patterns using single or multiple yarns may be used. For example, rib patterns or waffle patterns may be used to create 3D features. Terry weave may create loop three dimensional (3D) features. Jacquard weaving may create specialized patterns with multiple yarns. These technologies combined with a choice of yarn for a given pattern, makes it possible to modulate local pad properties. For example, a polyester yarn, nylon yarn or KEVLAR (poly(azanediyl-1,4-phenyleneazanediylterephthaloyl) yarn may be selectively applied to create high modulus and low modulus domains of desired size distributed in the pad. In another example, hydrophilic and hydrophobic yarns may be selectively applied to modulate slurry transport.

In an embodiment, the polishing pad comprises:
a textile layer,
a compressible layer; and
a water impermeable layer disposed between the textile layer and the compressible layer.

The top surface of the textile layer may be configured to contact a wafer, and a bottom surface of the compressible layer may be configured to be affixed to a polishing table.

The textile layer may have at least part of a top surface comprised of single sided terry weave loops, wherein the top surface of the textile layer is opposite to a bottom surface thereof that is adjacent to a top surface of the water impermeable layer.

The textile layer may be made from more than one type of yarn construction such as denier, twist, filament, staple.

The terry loops may be 1.0 mm to 10 mm high and, preferably, 2 mm to 6 mm high.

The textile layer yarn may be made of one or more polymers including but not limited to poly vinyl alcohol (PVA), polyester, polyurethane, nylon, ultra-high molecular weight polyethylene (UHMWPE), polypropylene, acrylic, ethylene propylene diene monomer rubber (EPDM), polystyrene, acrylonitrile butadiene styrene (ABS), KEVLAR, aramid, liquid crystal polymer such as VECTRAN, and liquid crystal polyoxazole (PBO), preferably polyurethane, nylon, ultra-high molecular weight polyethylene (UHMWPE) aramid, KEVLAR, EPDM, and PVA and more preferably polyurethane, nylon, ultra-high molecular weight polyethylene (UHMWPE) or KEVLAR. VECTRAN is a manufactured fiber, spun from liquid-crystal polymer available by the Celanese corporation.

The textile layer may have a yarn count from about 50 to about 500 per inch in warp and from about 50 to about 500 per inch in weft.

The Terry loop density may be from about 100 to about 10000 per inch².

The Terry loops may be arranged in a pattern including linear, circumferential, spiral, arc, or some other geometric arrangement.

The textile layer may comprise a yarn of from about 50 to about 2500 denier and preferably from about 200 to about 1500 denier.

The textile layer may be made by interlacing two sets of yarns or threads at right angles to each other. The two sets of the yarns or threads are referred to as the warp (lengthwise) and weft (crosswise). The textile layer may comprise warp and weft each containing yarns made of different materials. The Terry loops may be formed with yarn of yet another material using a weaving technique known as terry cloth” or “terry toweling” which includes adding at least one additional yarn which is woven into the textile layer's basic structure to form the loops. The yarn or yarns used to create the Terry loops may be referred to as the pile yarn. By basic structure of the textile layer we refer to the textile layer without the Terry loops and may also be referred to as the woven fabric base.

The water impermeable layer may be made of at least one of thermoplastic polyurethane, acrylic or polycarbonate polymer.

The water impermeable layer may be from about 25 to about 250 microns thick.

In an embodiment, the water impermeable layer may be thermally bonded to the textile layer. Thermal bonding may include heating the water impermeable layer till its surfaces become soft or melted prior to attaching the textile layer. The textile layer-impermeable layer composite is then attached to the compressible layer. The thermal heating of the water impermeable layer may be performed by any suitable means in a continuous or batch process.

One such method is to use a heated press, which applies heat and pressure simultaneously to make a permanent bond between the textile layer and impervious layer.

In an embodiment, the water impermeable layer may be bonded to the textile layer and to the compressible layer with an adhesive. The adhesive may be a thermal adhesive.

The compressible layer may be a woven 3D fabric.

The compressible layer may be a closed cell foam.

The compressible layer may be a non-woven textile.

The compressible layer may be from about 0.5 mm to about 2.5 mm thick.

The polishing pad is advantageous because, inter alia, may reduce slurry use by improving slurry transport and may also completely eliminate or reduce a need for diamond conditioning to maintain slurry transport.

These and other features of the present invention will become better understood by those skilled in the art of the present invention from the following detailed description of embodiments of the present invention in conjunction with some of the accompanying drawings.

### BRIEF DESCRIPTION OF THE DRAWINGS

The present invention is illustrated by way of example, and not limitation, in the figures of the accompanying drawings, in which:

FIG. 1 is a simplified schematic illustrating a typical polishing setup;

FIG. 2 is a simplified schematic illustrating a hard polishing pad;

FIG. 3 is a simplified schematic illustrating a soft polishing pad;

FIG. 4 is a simplified schematic illustrating a multilayer polishing pad which incorporates a textile layer according to an embodiment of the present invention;

FIG. 5 is a simplified schematic illustrating a textile polish layer and impermeable layer according to an embodiment of the present invention;

FIG. 6 is a simplified schematic illustrating a 3D fabric according to an embodiment of the present invention.

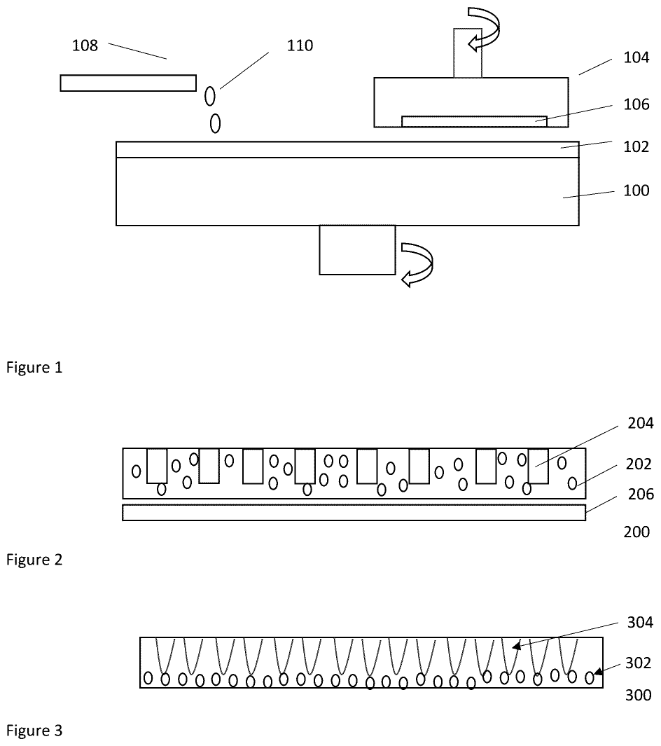

### DETAILED DESCRIPTION

According to a first aspect of the present invention a CMP pad is provided which reduces slurry consumption, reduces the need for reconditioning of the polishing surface, and can be readily customized to optimize the CMP process. The present invention also relates to a method for making the pad and a method of using the pad.

Accordingly in an embodiment, a pad in accordance with an embodiment of the invention includes a textile layer, an impervious layer, and a compressible layer. The textile layer may comprise a base fabric layer and a plurality of loops protruding over one side of the base fabric layer. The flat side of the base fabric layer which is opposite to the side with the protruding loops may be attached to the water impermeable layer which may in turn be attached to the compressible layer.

Typically cast urethane pads with Shore D hardness in the range of 55-75 are used for applications requiring planarization. One such hard pad, the IC1000 made by Dupont Electronic Materials, has a shore D hardness of 65. While such a pad provides good planarization, its WIWNU performance may not be adequate for all planarization tasks. In an attempt to improve WIWNU performance, a hard pad is typically stacked with a softer under-pad such as the SUBA IV.™. pad also made by Dupont Electronic Materials. The softer under-pad enables the top hard pad to provide global conformation of the pad surface against the wafer. The overall rigidity of the pad stack is thus lower than the rigidity of the hard pad alone. While this may help improve WIWNU, it also causes degradation in planarization performance. A typical polishing pad is 2-3 mm thick. The top layer or polish layer may be 1.5-2 mm thick; while the compressible soft pad underneath may be 0.5-1.0 mm thick.

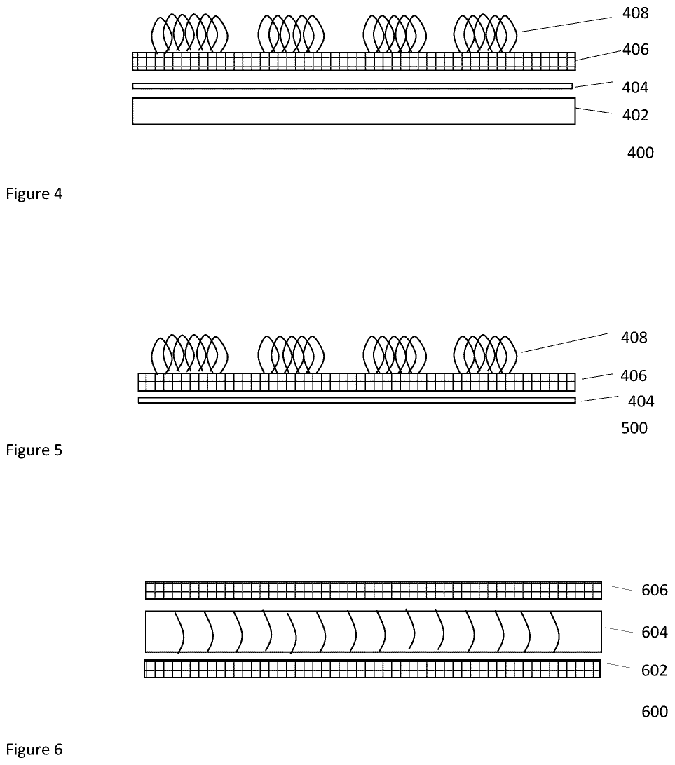

The present invention relates to a multilayer CMP pad design that reduces slurry consumption and pad conditioning, and provides a defect free wafer surface. FIG. 4 shows a pad 400 according to an embodiment of the invention. Pad 400 is comprised of a textile layer having a base fabric 406 which may be a woven base fabric and yarn loops 408. The yarn loops may be Terry loops. The loops may be laid out in groups with open space in between or arranged in rectangular pattern such that they form the periphery with open space in between. The loops may yet be arranged such that groups of high modulus yarn are interdigitated with low modulus yarn in a predetermined pattern. The textile layer may be from about 1 mm to about 3 mm thick. The woven textile layer is attached to a water impervious layer 404, which may be thermoplastic polyurethane or polyester and may be 25 microns to 250 microns thick. The water impervious layer 404 may be thermally bonded to the textile layer to have a permanent bond. The other side of the water impervious layer 404 may be attached to compressible layer 402. The compressible layer 402 may be, for example, a closed cell foam or elastomeric solid sheet or a nonwoven fabric or a 3D fabric. The thickness of the compressible layer 402 may be from about 0.5 mm to about 1.5 mm.

FIG. 5 shows a textile layer (406, 408) and water impervious layer 404. The textile layer and impervious layer are thermally bonded using a heat press. Bonding is accomplished by overlaying textile layer with an impervious layer and applying heat and pressure in a press heated to above softening temperature of the impervious layer.

FIG. 6 shows an example of a 3D fabric 600 which may be used as the compressible layer 402 of the pad 400, which contains a top fabric 606 and a bottom fabric 602 which may be same or different weave structures, and a connecting yarn layer 604. The connecting yarn layer 604 may be independently varied to modulate compressibility of the 3D fabric.

In an embedment of the present invention, the textile layer may comprise of engineered yarns (also referred to as threads or fibers) and textile technology to create the base fabric and the woven loops protruding vertically over one side of the base fabric. This structure of the pad provides high performance, reduced slurry consumption and reduced need for reconditioning of the surface of the pad. Also, the manufacturing method for making the pad is advantageous because it provides a controlled polishing surface with desired textured surface patterns using the yarn loops.

Using a weaving process allows creating an interconnected network of fibers/yarn in X-Y orientation which may be varied to generate features in Z direction. However, the invention may not be limited to using the weaving method for making the base fabric and the loops on the base fabric. Other suitable methods may be used.

For example, knitting is another process for creating textiles and consists of creating fabric by making a series of interconnected loops. Knitting is similarly precise and can generate 3D features as well. Tufting is yet another method of weaving that is useful for creating 3D features. In tufting, typically used for making carpets, individual loops of yarn are woven in vertical orientation to base fabric. While this approach has lower resolution than weaving or knitting, and is used for making thicker substrates like carpets, it is very flexible in applying specific yarns in specific locations. A surface with highly controlled mechanical as well fluid transport properties can be created using this technique. For example, yarn with high and low modulus may be applied to create islands of high modulus surrounded by low modulus or vice versa. A 3D feature may be defined as one where features are created on the surface by specifically applying one or more yarn weaves over and above the yarn in adjacent surface. Weave patterns, Twill, Rib, waffle etc. are well known to those in the art. In these weaving styles, fabric has texture due to weave pattern that places yarns preferentially in certain locations over others. Terry is another such process where additional yarn is woven into the base fabric and extends from the surface as loops.

According to an embodiment, a “Terry” weaving process is employed, though other patterns may also be employed. The Terry process is well known for creating a loop pattern on one or both sides of a fabric. Terry loops can be uniformly applied over the surface or arranged in any desired pattern. Terry may be single sided or double sided, where in loops extend on both sides of the fabric surface. For pads, it is preferable to have single sided terry in a desired pattern. Terry loops enable significantly higher surface area with the body due to flexing compliance of the loops. The present invention employs the terry weaving process with specially engineered fibers for providing a CMP pad with significantly enhanced texture and reduced slurry use. Engineered fiber material and fiber diameter may be used to modulate the polish response and design parameters like the size along with surface density of loops for optimizing the polish performance. Additionally, such surface enables more efficient distribution of slurry and chemicals onto the wafer surface. Besides the weaving pattern, several types of fibers may be combined to create a pad. For example, the loops may be woven from hydrophilic yarns such as polyurethane, polyester, nylon etc. while the base fabric may be woven from part of all hydrophobic yarn such as polypropylene or polyethylene. Such a pad would preferentially direct slurry towards the polish loops and, also efficiently remove debris and polish byproduct. A 100-2000 denier may be used to manufacture pads with suitable characteristics. Though higher or lower denier may also be used. Generally, monofilament yarns are desirable over staple or short fiber yarns to minimize potential for fiber disintegration. However, staple yarns provide more flexibility in tuning properties, therefore staple yarn pads may be desirable for specific applications. Yarns may be made from fibers containing abrasive such as silicon dioxide, ceria, alumina, silicon carbide, boron nitride or other abrasives typically used in suspensions used for polishing. Nominal particle size, similar to the ones in polish suspensions (50 nm to 250 nm) may be used. A 20-50 vol % abrasive may be used. Abrasive containing yarn may be used in conjunction with nonabrasive containing yarn to make a pad. A pad may have yarns of more than one denier rating, for example the base fabric may be made of high denier yarn while terry loops may be constructed from low denier or vice versa. Therefore, it is understood that Terry is one method for creating surface texture by weaving or knitting. There are other weaving/knitting patterns that may be used to generate 3D structures useful for the application. An advantage of the pad of the present invention is that it enables reduction in slurry usage compared to existing CMP pads. Slurry usage is one of the highest single consumable costs in semiconductor fabrication today. Yet another advantage is potential elimination or minimization of diamond pad conditioning. Surface cleaning with a bristle cleaning brush may still be required.

In one example, polish layer was made from 300 denier polyester yarn with loop height of ˜3 mm and total thickness of ˜3.3 mm. Loops were arranged in 10 mm×10 mm squares with 2 mm gap between squares. Polish layer was thermally bonded to polyurethane film 100 micron thick, PT 9200 film from Covestro, using a heat press. Polyurethane bonded textile layer was adhered to 0.062 inch thick, closed cell polyurethane foam (#4701-60-25062-04) from Rogers Corporation, using pressure sensitive adhesive FT-1150, from Avery Dennison. Another pressure sensitive adhesive FT-8305 was applied to the opposite side of polyurethane foam to affix the pad to polish table.

In another example, polish layer was made from 300 denier Nylon and 300 denier polypropylene yarn and loop height of ˜2.5 mm and total thickness of ˜2.8 mm. Loops were arranged in alternating 10 mm×10 mm squares with 2 mm gap between squares. Polish layer was thermally bonded to polyurethane film 125 micron thick, PT 7500 film from Covestro, using a heat press. Polyurethane bonded textile layer was adhered to 0.062 inch thick, closed cell polyurethane foam (#4701-60-25062-04) from Rogers Corporation, using pressure sensitive adhesive FT-1150, from Avery Dennison. Another pressure sensitive adhesive FT-8305 was applied to the opposite side of polyurethane foam to affix the pad to polish table.

Although the invention has been described with specific embodiments it should be understood that many other embodiments may be envisaged by those skilled in the art to which the present invention pertains without departing from the scope, spirit, or technical concepts of the present inventions defined by the following claims.

What is claimed is:

1. A polishing pad comprising:
a textile layer;
a compressible layer; and
a water impermeable layer, the water impermeable layer being disposed between the textile layer and the compressible layer.

2. The polishing pad of claim 1, wherein the textile layer has at least part of a top surface comprised of single sided yarn loops, wherein the top surface of the textile layer is opposite to a bottom surface thereof that is adjacent to a top surface of the water impermeable layer.

3. The polishing pad of claim 1, wherein the yarn loops are terry loops and wherein the textile layer is a woven textile layer made from more than one type of yarn construction such as denier, twist, filament, staple.

4. The polishing pad of claim 3, wherein the terry loops are from about 1.0 mm to about 10 mm high.

5. The polishing pad of claim 1, wherein the textile layer is made of a yarn made of one or more polymers including poly vinyl alcohol (PVA), polyester, polyurethane, nylon, ultra-high molecular weight polyethylene (UHMWPE), polypropylene, acrylic, EPDM, polystyrene, ABS, KEVLAR, aramid, liquid crystal polymer such as VECTRAN fiber, and liquid crystal polyoxazole.

6. The polishing pad of claim 1, wherein the textile layer comprises a base fabric that is a woven fabric having a yarn count of from about 50 to about 500 per inch in warp and from about 50 to about 500 per inch in weft.

7. The polishing pad of claim 1,
wherein the textile layer comprises a base fabric that is a woven fabric and a plurality of terry loops woven into the base fabric and protruding over a top surface of the woven fabric,
wherein the base fabric has a yarn count of from about 50 to about 500 per inch in warp and from about 50 to about 500 per inch in weft, and
wherein a terry loop density is from about 100 to about 10000 per inch².

8. The polishing pad of claim 7, wherein the terry loops are arranged in a pattern including linear, circumferential, spiral, arc, or other geometric shape.

9. The polishing pad of claim 1, wherein the textile layer comprises a yarn of from 50 to about 2500 denier.

10. The polishing pad of claim 1, wherein the textile layer is a woven fabric comprising warp and weft yarns made of different materials and wherein the terry loops are formed with yarn of yet another material.

11. The polishing pad of claim 1, wherein the water impermeable layer is made of at least one of thermoplastic polyurethane, acrylic or polycarbonate polymer.

12. The polishing pad of claim 1, wherein the water impermeable layer is from 25 to about 250 microns thick.

13. The polishing pad of claim 1, wherein the water impermeable layer is thermally bonded to the textile layer.

14. The polishing pad of claim 1, wherein the water impermeable layer is bonded to the compressible layer with an adhesive.

15. The polishing pad of claim 1, wherein the compressible layer is a woven 3D fabric, or a closed cell foam, or a non-woven textile, and is from about 0.5 mm to about 2.5 mm thick.

16. A method of using a polishing pad, the method comprising:
removably attaching the pad to a polish table, applying a wafer to the wafer holder, and pressing a rotating wafer against the rotating polish table with suitable pressure to remove the film on the wafer.

17. The method of claim 16, wherein a textile layer of the pad comprises a woven base fabric and terry loops protruding over a top surface of said base fabric.

18. The method of claim 16,
wherein the pad comprises a textile layer, a compressible layer; and
a water impermeable layer, the water impermeable layer being disposed between the textile layer and the compressible layer,
wherein the textile layer includes a base fabric and a plurality of terry loops formed on a side of the base fabric facing the wafer,
wherein the terry loops are from about 1.0 mm to about 10 mm high and have a density of from about 100 to about 10000 per square inch, and
wherein the woven base fabric has a yarn count of from about 50 to about 500 per inch in warp and from about 50 to about 500 per inch in weft.
